(19) United States
(12) Patent Application Publication
(10) Pub. No.: US 2012/0138143 A1
(43) Pub. Date: Jun. 7, 2012

(54) PHOTOELECTRIC CONVERSION MODULE

(75) Inventor: Toshio Yagiura, Kobe-shi (JP)

(73) Assignee: Sanyo Electric Co., Ltd., Moriguchi-shi (JP)

(21) Appl. No.: 13/389,892

(22) PCT Filed: Oct. 21, 2010
(86) PCT No.: PCT/JP2010/068610

§ 371 Date: Feb. 10, 2012

(30) Foreign Application Priority Data
Oct. 30, 2009 (JP) 2009-250042

(51) Int. Cl. H01L 31/0224

(52) U.S. Cl. 136/256

(57) ABSTRACT

In order to inhibit peeling of a backside electrode of a photoelectric conversion module, a photoelectric conversion element, which is formed by sequentially layering a transparent conductive layer (22), a photoelectric conversion unit (24), and a backside electrode (26) over a substrate (20), and a first electricity collecting electrode (28), which is for collecting the current generated by the photoelectric conversion element, are provided. In this configuration, the first electricity collecting electrode (28) is formed across the backside electrode (26) and the transparent conductive layer (22) on a removed region (A) of a panel end.

### TECHNICAL FIELD

The present invention relates to a photoelectric conversion module.

### BACKGROUND ART

Photoelectric conversion modules which use polycrystalline, microcrystalline, or amorphous silicon are known. In particular, a photoelectric conversion module having a structure in which thin films of microcrystalline or amorphous silicon are layered has attracted much attention from the viewpoints of resource consumption, cost reduction, and superior efficiency.

FIG. 7 is a cross-sectional schematic diagram of a basic structure of a photoelectric conversion module 100. The photoelectric conversion module 100 generally has a structure in which a transparent electrode 12, a photoelectric conversion unit 14, and a backside electrode 16 are layered over a transparent substrate 10 such as glass, and generates electric power by allowing light to be incident through the transparent substrate 10. In such a photoelectric conversion module, photoelectric conversion elements are integrated in series or in parallel, and an electricity collecting electrode 18 for collecting electricity from these elements is formed over the backside electrode 16 of the element at a panel end of the photoelectric conversion module 100. In addition, a technique is disclosed (for example, in Patent Literature 1) in which a height of a soldering dip lead is adjusted in order to improve the strength of the soldering material used in the electricity collecting electrode 18 or the like.

### Related Art References

### [Patent Literature]

### [Patent Literature 1] JP 2007-273908 A

### DISCLOSURE OF INVENTION

### Technical Problem

A joining force is weak at an interface between the backside electrode 16 and the photoelectric conversion unit 14, and there is a possibility of the backside electrode 16 peeling off along with the electricity collecting electrode 18 when the electricity collecting electrode 18 is formed over the backside electrode 16. As a result, there is a possibility that the photoelectric conversion module 100 will be damaged or the photoelectric conversion efficiency will be reduced.

### Solution to Problem

According to one aspect of the present invention, there is provided a photoelectric conversion module comprising a photoelectric conversion element in which a transparent conductive layer, a power generating layer, and a backside electrode are sequentially layered over a substrate, and an electricity collecting electrode which collects a current generated by the photoelectric conversion element, wherein the electricity collecting electrode is formed across the backside electrode and at least one of the transparent conductive layer and the substrate.

### Advantageous Effects of Invention

According to various aspects of the present invention, peeling of the backside electrode in the photoelectric conversion module can be inhibited.

### BRIEF DESCRIPTION OF DRAWINGS

FIG. 1 is a plan view showing a structure of a photoelectric conversion module in a preferred embodiment of the present invention.

FIG. 2 is a cross sectional diagram showing a structure of a photoelectric conversion module in a preferred embodiment of the present invention.

FIG. 3 is a cross sectional diagram showing a structure of a photoelectric conversion module in a preferred embodiment of the present invention.

FIG. 4 is a cross sectional diagram showing a structure of a photoelectric conversion module in a preferred embodiment of the present invention.

FIG. 5 is a cross sectional diagram showing another example structure of a photoelectric conversion module in a preferred embodiment of the present invention.

FIG. 6 is a cross sectional diagram showing another example structure of a photoelectric conversion module in a preferred embodiment of the present invention.

FIG. 7 is a cross sectional diagram showing a structure of a photoelectric conversion module in related art.

### BEST MODE FOR CARRYING OUT THE INVENTION

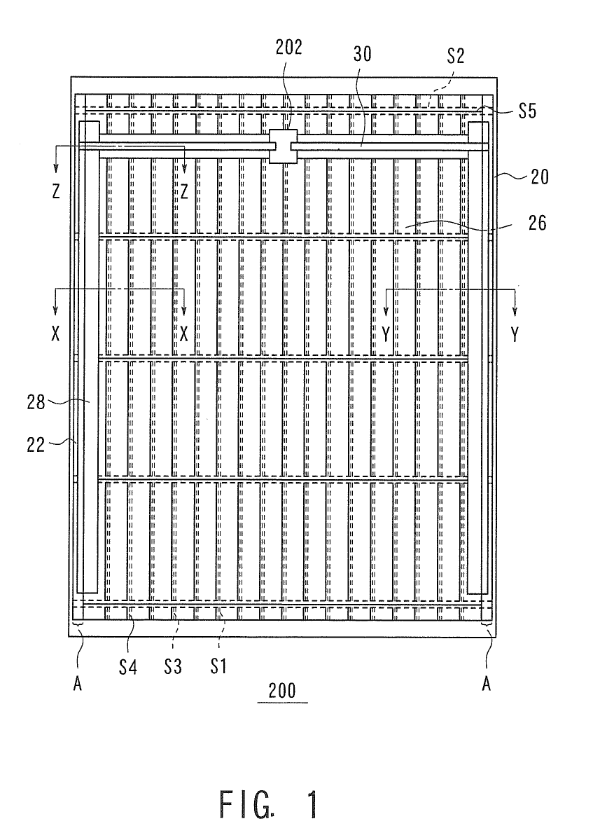

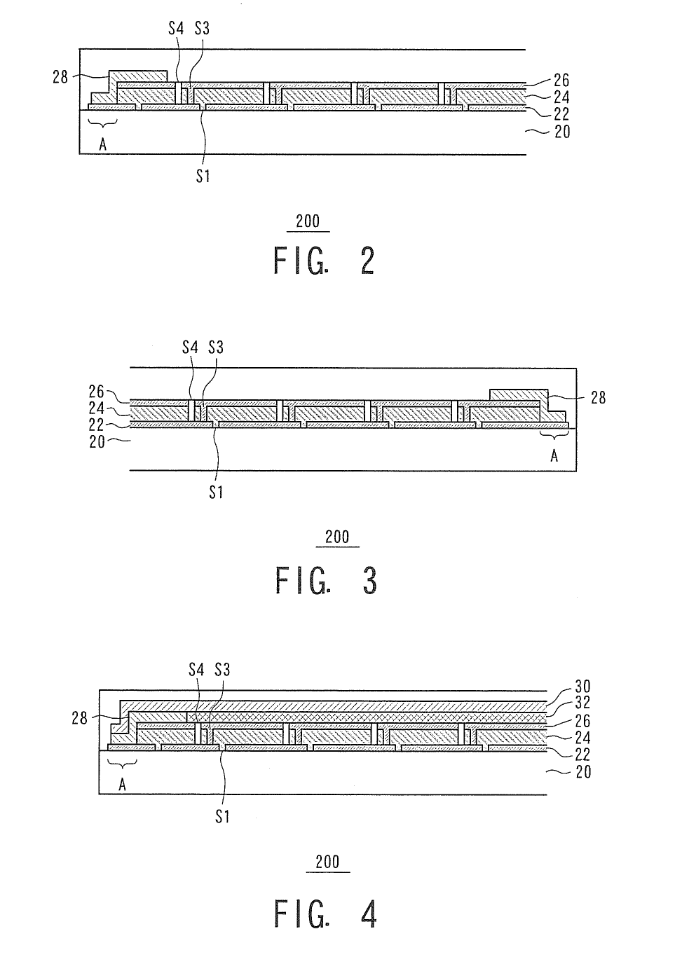

As shown in a plan view of FIG. 1 and cross sectional diagrams of FIGS. 2, 3, and 4, a photoelectric conversion module 200 according to a preferred embodiment of the present invention comprises a substrate 20, a transparent conductive layer 22, a photoelectric conversion unit 24, a backside electrode 26, a first electricity collecting electrode 28, and a second electricity collecting electrode 30. FIG. 2 is a cross sectional diagram along an X-X line in FIG. 1, FIG. 3 is a cross sectional diagram along a Y-Y line in FIG. 1, and FIG. 4 is a cross sectional diagram along a Z-Z line in FIG. 1.

For the substrate 20, a transparent substrate having an optical characteristic which allows light of a wavelength used in the photoelectric conversion at the photoelectric conversion unit 24 to transmit through is employed. For the substrate 20, for example, glass, plastic, or the like is used. For the transparent conductive layer 22, a transparent conductive oxide (TCO) in which tin oxide (SnO2), zinc oxide (ZnO), indium tin oxide (ITO), or the like is doped with tin (Sn), antimony (Sb), fluorine (F), aluminum (Al), or the like may be employed.

On the transparent conductive layer 22, a slit 51 for connecting the photoelectric conversion elements in series is formed. The slit S1 may be formed by laser machining. For the laser machining, a YAG laser of a wavelength of 1064 nm is preferably employed. A power of a laser beam emitted from a laser device is adjusted, the laser beam is irradiated from the side of the transparent conductive layer 22, and the laser beam is continuously scanned in the direction of the slit S1, so that the slit S1 can be formed. Alternatively, the laser for forming the slit S1 may be irradiated from the side of the substrate 20.

In addition, as shown in FIG. 1, a slit S2 for connecting the photoelectric conversion elements in parallel is formed on the transparent conductive layer 22. The slit S2 may be formed by laser machining. For the laser machining, a YAG laser of a wavelength of 1064 nm is preferably employed. The power of the laser beam emitted from the laser device is adjusted, the laser beam is irradiated from the side of the transparent conductive layer 22, and the laser beam is continuously scanned in the direction of the slit S2, so that the slit S2 can be formed. Alternatively, the laser for forming the slit S2 may be irradiated from the side of the substrate 20.

The photoelectric conversion unit 24 receives light transmitted through the substrate 20 and the transparent conductive layer 22, and executes photoelectrical conversion. The photoelectric conversion unit 24 is formed with semiconductor layers which are joined in the form of a PN-junction or a PIN-junction. The photoelectric conversion unit 24 is not particularly limited, and may be, for example, an amorphous silicon (a-Si) photoelectric conversion unit, a microcrystalline (μc-Si) photoelectric conversion unit, or a tandem structure of these units. The photoelectric conversion unit 24 may be formed using plasma CVD or the like.

A slit S3 for connecting the photoelectric conversion elements in series is formed on the photoelectric conversion unit 24. The slit S3 is formed at a position near the slit S1 and not overlapping the slit S1, along the direction of the slit S1, and to a surface of the transparent conductive layer 22. The slit S3 may be formed by laser processing. For the laser processing, a YAG laser of a wavelength of 532 nm (second harmonic) is preferably employed. The power of the laser beam is adjusted, the laser beam is irradiated from the side of the substrate 20, and the laser beam is scanned in the direction of the slit S3, so that the slit S3 can be formed.

The backside electrode 26 is provided on the back surface side of the photoelectric conversion module 200 for outputting electric power from the photoelectric conversion unit 24. The backside electrode 26 is formed covering the photoelectric conversion unit 24 and the slit S3. The backside electrode 26 is preferably made of a reflective metal. Alternatively, the backside electrode 26 is preferably formed with a layered structure of the reflective metal and a transparent conductive oxide (TCO). As the reflective metal, silver (Ag), aluminum (Al), or the like may be used. As the transparent conductive oxide (TCO), tin oxide (SnO2), zinc oxide (ZnO), indium tin oxide (ITO), or the like may be used.

A slit S4 for connecting the photoelectric conversion elements in series is formed on the backside electrode 26. The slit S4 is formed at a position near the slit S3 and not overlapping the slits S1 and S3, and to the surface of the transparent conductive layer 22 to divide the photoelectric conversion unit 24 and the backside electrode 26 along the directions of the slits S1 and S3. The slit S4 is formed by a laser processing. For the laser processing, a YAG laser of a wavelength of 532 nm (second harmonic) is preferably employed. The power of the laser beam is adjusted, the laser beam is irradiated from the side of the substrate 20, and the laser beam is scanned in the direction of the slit S4 so that the slit S4 can be formed.

In addition, as shown in FIG. 1, a slit S5 for connecting the photoelectric conversion elements in parallel is formed on the backside electrode 26. The slit S5 is formed overlapping the slit S2 and along the slit S2. The slit S5 is formed to the surface of the substrate 20 to divide the photoelectric conversion unit 24 and the backside electrode 26 formed in the slit S2. The slit S5 is formed by laser processing. For the laser processing, a YAG laser of a wavelength of 532 nm (second harmonic) is preferably employed. The power of the laser beam is adjusted, the laser beam is irradiated from the side of the substrate 20, and the laser beam is scanned in the direction of the slit S5 so that the slit S5 can be formed.

In addition, the photoelectric conversion unit 24 and the backside electrode 26 at a panel end of the photoelectric conversion module 200 are removed along the directions of the slits S1, S3, and S4, to form a removed region A with the transparent conductive layer 22 remaining. The removed region A may be formed by laser processing. For the laser processing, a YAG laser of a wavelength of 532 nm (second harmonic) is preferably employed. The power of the laser beam is adjusted, the laser beam is irradiated from the side of the substrate 20, and the laser beam is scanned in the direction of the panel edge, so that the removed region A can be formed.

The first electricity collecting electrode 28 is formed for collecting output electric power of the photoelectric conversion elements divided in parallel by the slits S2 and S5. Therefore, the first electricity collecting electrode 28 is formed across the slits S2 and S5 to connect the backside electrodes 26 of the panel end of the photoelectric conversion module 200 in parallel to each other. In this process, the first electricity collecting electrode 28 is formed from the backside electrode 26 and across the removed region A. In other words, the first electricity collecting electrode 28 is formed from the surface of the backside electrode 26, over the side surfaces of the backside electrode 26 and the photoelectric conversion unit 24, and to the surface of the transparent conductive layer 22. In this process, it is only necessary for the first electricity collecting electrode 28 to be formed to a degree to not reach the slits S1, S3, and S4 (in particular, the slit S4).

It is only necessary for the first electricity collecting electrode 28 to be formed including a material having a sufficient conductive characteristic for collecting electricity. The first electricity collecting electrode 28 may be, for example, a conductive tape in which a conductive material is mixed on the surface or inside, a line-shaped solder, a structure applied with a silver paste by screen printing or the like.

By forming the first electricity collecting electrode 28 from the backside electrode 26 and across the removed region A, it is possible to inhibit peeling of the backside electrode 26 from the interface with the photoelectric conversion unit 24. It can be deduced that, because the contact characteristic of an interface between the transparent conductive layer 22 of the removed region A and the first electricity collecting electrode 28 is superior, the peeling of the backside electrode 26 from the photoelectric conversion unit 24 is inhibited by the first electricity collecting electrode 28. In particular, the first electricity collecting electrode 28 is preferably formed having a broader area over the transparent conductive layer 22 than an area over the backside electrode 26. With such a structure, the peeling inhibition effect can be more strongly obtained. In addition, the first electricity collecting electrode 28 is preferably formed in the removed region A to also cover an end of the transparent conductive layer 22. With such a structure, intrusion of moisture or the like from the outside of the photoelectric conversion module 200 can be prevented with the first electricity collecting electrode 28, and degradation of the transparent conductive layer 22 can be inhibited.

As shown in FIG. 4, the second electricity collecting electrode 30 is an electrode for connecting the first electricity collecting electrode 28 to a connector 202. The second electricity collecting electrode 30 electrically connects the first electricity collecting electrode 28 and the connector 202, and it is only necessary for the second electricity collecting electrode 30 to be formed including a material having a sufficient conductive characteristic for electricity collection. The second electricity collecting electrode 30 may be, for example, a conductive tape in which a conductive material is mixed on the surface or inside, a solder formed with a method such as screen printing, or the like. Preferably, an insulating member 32 is provided, in order to prevent contact of the second electricity collecting electrode 30 with the backside electrode 26 and the photoelectric conversion unit 24 in a region between the first electricity collecting electrode 28 and the connector 202.

In this case, preferably, the second electricity collecting electrode 30 is provided extending to a region over the first electricity collecting electrode 28 formed in the removed region A. With such a configuration, the peeling of the backside electrode 26 and the photoelectric conversion unit 24 can more preferably be inhibited compared to a configuration where the second electricity collecting electrode 30 is provided extending only to the first electricity collecting electrode 28 formed over the backside electrode 26.

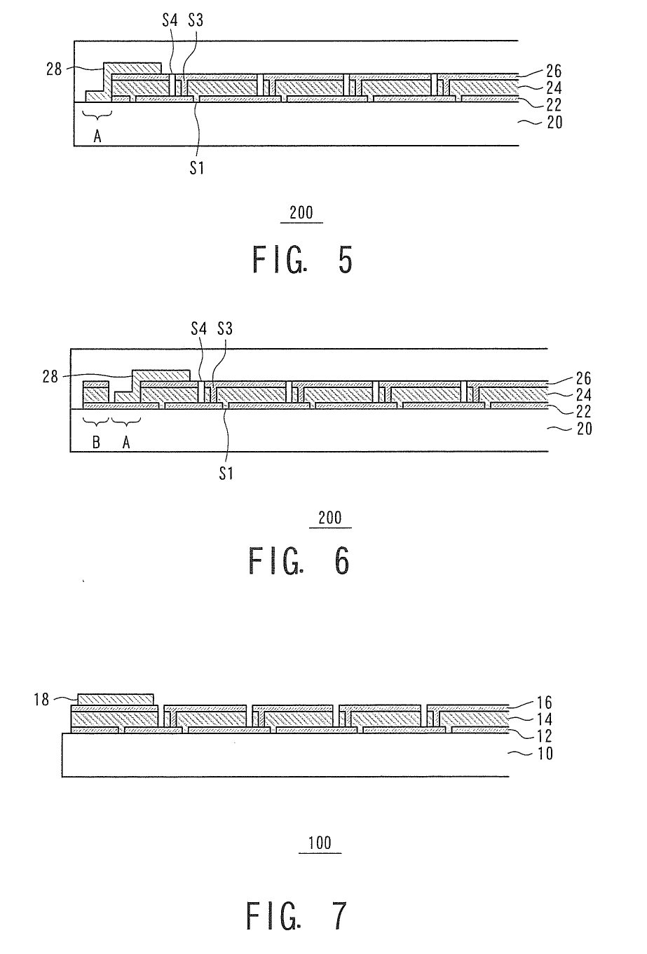

Alternatively, as shown in FIG. 5, the transparent conductive layer 22 may also be removed in the removed region A so that only the substrate 20 remains in the removed region A. In this case, the first electricity collecting electrode 28 is formed from the backside electrode 26 and across the substrate 20 in the removed region A. In such a structure also, the peeling of the backside electrode 26 from the interface with the photoelectric conversion unit 24 can be inhibited. In this case also, it can be deduced that, because the contact characteristic of the interface between the substrate 20 and the first electricity collecting electrode 28 in the removed region A is superior, the peeling of the backside electrode 26 from the photoelectric conversion unit 24 can be inhibited by the first electricity collecting electrode 28.

Alternatively, as shown in FIG. 6, an island portion B may be formed on a side nearer to the panel end than the removed region A, in which at least one of the photoelectric conversion unit 24 and the backside electrode 26 remains. With such a configuration, it is possible to inhibit intrusion of moisture from the panel end, and consequently, degradation of the first electricity collecting electrode 28 and the photoelectric conversion unit 24 inside the panel. In the case of the structure in which only the substrate 20 remains in the removed region A as shown in FIG. 5 also, the island portion B may be formed on a side nearer to the panel end than the removed region A by leaving at least one of the photoelectric conversion unit 24 and the backside electrode 26, so that similar advantages can be obtained.

### Explanation of Reference Numerals

10 TRANSPARENT SUBSTRATE; 12 TRANSPARENT ELECTRODE; 14 PHOTOELECTRIC CONVERSION UNIT; 16 BACKSIDE ELECTRODE; 18 ELECTRICITY COLLECTING ELECTRODE; 20 SUBSTRATE; 22 TRANSPARENT CONDUCTIVE LAYER; 24 PHOTOELECTRIC CONVERSION UNIT; 26 BACKSIDE ELECTRODE; 28 FIRST ELECTRICITY COLLECTING ELECTRODE; 30 SECOND ELECTRICITY COLLECTING ELECTRODE; 32 INSULATING MEMBER; 100, 200 PHOTOELECTRIC CONVERSION MODULE; 202 CONNECTOR.

1. A photoelectric conversion module comprising:
a photoelectric conversion element in which a transparent conductive layer, a power generating layer, and a backside electrode are sequentially layered over a substrate; and
an electricity collecting electrode which collects a current generated by the photoelectric conversion element, wherein
the electricity collecting electrode is formed across the backside electrode and at least one of the transparent conductive layer and the substrate.

2. The photoelectric conversion module according to claim 1, wherein the electricity collecting electrode has an area over the transparent conductive layer and the
substrate broader than an area over the backside electrode.

3. The photoelectric conversion module according to claim 1, wherein
an island portion in which at least one of the transparent conductive layer, the power generating layer, and the backside electrode remains is provided on an outer side of the electricity collecting electrode.

4. The photoelectric conversion module according to claim 1, wherein
the electricity collecting electrode is formed also covering an end of the transparent conductive layer when the electricity collecting electrode is formed over the transparent conductive layer.

5. The photoelectric conversion module according to claim 1, further comprising:
an electrode which further collects electricity from the electricity collecting electrode, wherein
the electrode is formed across the electricity collecting electrode formed over at least one of the transparent conductive layer and the substrate.
